(19) United States
(12) Patent Application Publication
(10) Pub. No.: US 2013/0056070 A1
(43) Pub. Date: Mar. 7, 2013

(54) APPARATUS AND METHOD FOR ENHANCING INVERTED ORGANIC SOLAR CELLS BY UTILIZING LIGHT ILLUMINATION

(71) Applicants: Sheng-Fu Horng, Hsinchu City (TW); Jen-Chun Wang, Hsinchu City (TW); Cheng-Yueh Lu, Hsinchu City (TW); Jui-Lin Hsu, Hsinchu City (TW); Ming-Kun Lee, Hsinchu City (TW); Yun-Ru Hong, Hsinchu City (TW); Hsin-Fei Meng, Hsinchu City (TW); Yuan-Lin Yang, Hsinchu City (TW); Tsung-Te Chen, Hsinchu City (TW)

(72) Inventors: Sheng-Fu Horng, Hsinchu City (TW); Jen-Chun Wang, Hsinchu City (TW); Cheng-Yueh Lu, Hsinchu City (TW); Jui-Lin Hsu, Hsinchu City (TW); Ming-Kun Lee, Hsinchu City (TW); Yun-Ru Hong, Hsinchu City (TW); Hsin-Fei Meng, Hsinchu City (TW); Yuan-Lin Yang, Hsinchu City (TW); Tsung-Te Chen, Hsinchu City (TW)

(73) Assignee: NATIONAL TSING HUA UNIVERSITY

(21) Appl. No.: 13/334,902

(22) Filed: Dec. 22, 2011

(30) Foreign Application Priority Data
Sep. 2, 2011 (TW) 100131631

(51) Int. Cl. H01L 51/46; H01L 31/18; H01L 31/0224

(52) U.S. Cl. 136/263; 136/256; 438/98; 257/E31.124

(57) ABSTRACT

Disclosed is an apparatus and method for generating inverted organic solar cells and which required no electron selective layer, were fabricated and their power conversion efficiency was found to improve irreversibly with post-processing light soaking for a period. X-Ray photoelectron spectroscopy characterization further revealed segregation in surface composition at the interface and was found to explain the current density-voltage measurements. In addition, the light soaked devices were found to exhibit an extended lifetime as compared to conventional devices. Since no electron selective layer was required, light soaking may be considered as a cost-effective method to achieve efficient inverted organic solar cells.

### BACKGROUND OF THE INVENTION

1. Field of the Invention

The present invention relates to an organic solar cell, in particular to a highly efficient inverted organic solar cell without an electron selective layer.

2. Description of the Related Art

Due to the polluted environment and increasing shortages with our energy supplies, solar cells are currently becoming the most reliable energy replacement for mankind, and the current development of solar cells is still mainly concentrated on single-crystal silicone and polycrystalline silicone solar energy cells.

Moreover, the market for silicon-based thin film solar energy cells (Microcrystalline silicon and amorphous silicon) is gradually growing, and besides silicon-based solar energy cells, there are group III-V and II-VI inorganic compound solar energy cells.

However previous production costs have been too high, creating obstacles for future applications, and looking to the future there are concerns regarding poor stability and environmental questions, leading to green energy considerations and research of organic solar energy cells still being a focus of research by all parties.

In the development of organic macromolecular solar energy cells, the evolution has been from single layer structures to double-layer structures. The most recent development has been higher efficiency bulk heterojunction (BHJ) compound material structures being the organic photovoltaic (OPV) device of the active layer, because of its lower production costs, flexibility, lighter weight and ability to be produced. Because of this it has quickly become the focus for researchers.

The most concrete characteristic of the BHJ OPV is the basic structure integrating/fusing/merging poly (3-hexylthiophene) to be the electron donor and the derivative PCBM ([6,6]-phenyl C61-butyric acid methyl ester) of the C60 to be the electron acceptor.

In recent years, all kinds of new donors and acceptors combining to form organic solar cells (OSC) have already successfully obtained high power conversion efficiencies (PCE), the highest exceeding 7%, thereby showing the increasing commercial uses and future for organic solar cells.

Traditional organic solar cells mostly comprise a low working function cathode, which oxidizes easily in air. Therefore these devices display a low level of stability in air. Besides this, the vertically distributed donors and acceptors in BHJ OSC have a higher concentration of recipients displayed at the indium tin oxide ends, and this kind of vertical concentration gradient of the donors and acceptors is not ideal for charge transfer in traditional organic solar cells.

Ways to overcome these shortcomings are to utilize vertically concentrated distribution and only use stable electrode material having a high work function in the inverted structure. Before this, thin film material such as Cs2CO3 [symbol] TiO₂ and ZnO, were used as the electron selective layer, to increase the electron transfer ability in the inverted OPV device.

Moreover, the electron selective layer of the inverted OPV device still needs to pass through complex processing steps, such as Atomic Layer Deposition (ALD), the problem of controlled distribution of the nano-coating and such technologies, and only then can the Atomic Layer Deposition (ALD) on the flexible substrate reach a power conversion efficiency rate of 4.18%. Because of this, for the inverted OPV device to achieve a higher efficiency rate, there's still no way to avoid a complicated production process of the electron selective layer.

Because of the above, in view of the current technologies and shortcomings, the applicant wishes to simplify the production method, lower costs and at the same time maintain high conversion efficiency rates, and has therefore invented “apparatus and method for enhancing inverted organic solar cells by utilizing light illumination” to improve on the above conventional means and shortcomings.

### SUMMARY OF THE INVENTION

The object of this invention is to simplify the production process of a complex inverted organic solar cell, that is, to remove the electron selective layer out of the general inverted organic solar cells, and achieve its high photoelectric conversion efficiency rates with irreversible features, and effectively extend its usage lifetime.

To achieve the above-mentioned goal, this invention provides an inverted organic solar cell, comprising: a substrate; a light absorbing layer located on the substrate; a hole transport layer located on the light absorbing layer; and a metal electrode located on the hole transport layer, wherein, the inverted organic solar cell can achieve high conversion efficiency rates for a long time after the inverted organic solar cell has passed through a continuous illumination for a period of time.

Preferably, the substrate is a glass or plastic substrate coated with transparent conductive film such as indium tin oxide (ITO) or aluminum doped zinc oxide (ZnO:Al).

Preferably, a material of the light absorbing layer is one selected from the following group consisting of: P3HT(3-hexylthiophene) [symbol] C60 derivative [symbol] PTB1 [symbol] PTB2 [symbol] PTB3 [symbol] PTB4 [symbol] PTB5 [symbol] PTB6 [symbol] PTB7 and the group consisting of any combinations thereof.

According to the above mentioned purpose, the present invention additionally proposes a production method of inverted organic solar cell, comprising the following steps: (a) Providing a substrate; (6) Forming a light absorbing layer on the substrate; (c) Forming a hole transport layer on the light absorbing layer; and (d) Depositing a metal electrode on the hole transport layer, wherein the inverted organic solar cell can achieve high conversion efficiency rates for a long time after the inverted organic solar cell has passed through a continuous illumination for a period of time (the length of the continuous illumination is adjusted according to the selected material).

Preferably, in step (a), the substrate is a glass or plastic substrate coated with transparent conductive film such as indium tin oxide (ITO) or aluminum doped zinc oxide (ZnO:Al).

Preferably, the material of the light absorbing layer is one selected from the following group consisting of: P3HT(3-hexylthiophene) [symbol] C60 derivative [symbol] PTB1 [symbol] PTB2 [symbol] PTB3 [symbol] PTB4 [symbol] PTB5 [symbol] PTB6 [symbol] PTB7 and the group consisting of any combinations thereof.

Therefore, the effectiveness of this invention is not only to simplify the production process of a complex inverted organic solar cell, but also to reduce the use of components, and further reduce the production costs, which still maintain its highly photoelectric conversion efficiency rates, moreover, the usage lifetime of this invention is longer than that of the traditional inverted organic solar cells, which meets the requirements of the economy and environmental protection industry.

The invention, as well as its many advantages, may be further understood by the following detailed description and drawings in which:

### BRIEF DESCRIPTION OF THE DRAWINGS

FIG. 1 (a) is a structure diagram showing one embodiment of the invention, and (b) is an energy band diagram showing each layer material of one embodiment of the invention.

FIG. 2 is a production flow chart showing one embodiment of the invention.

FIG. 3 is the curve diagram showing a curve diagram the J-V characteristics of the as-prepared and light-soaked apparatus of the invention in the dark and under illumination.

FIG. 4 is the diagram showing the as-prepared and light-soaked apparatus of the invention, wherein (a) is the absorption and (b) is the EQE spectra.

FIG. 5 is the curve diagram showing a curve diagram the J-V characteristics of one embodiment of the invention post-annealed at (a) 50° C. and (b) 60° C., respectively.

FIG. 6 is the XPS spectra of S 2p obtained from the surface of P3HT/PCBM blend layers of one embodiment of the invention with different post-treatments.

FIG. 7 is the band diagrams of one embodiment of the invention, wherein (a) is V=0 V, (b) is forward bias and (c) is reverse bias.

FIG. 8 is AFM images of the surface of P3HT/PCBM blend layers of one embodiment of the invention, wherein (a) is as-prepared and (b) is light-soaked.

FIG. 9 is the evolution diagram of the performance parameters of one embodiment of the invention as a function of storage time, wherein (a) is PCE, (b) is Jsc, (c) is Voc and (d) is FF.

### DETAILED DESCRIPTION OF THE INVENTION

The technical characteristics and operation processes of the present invention will become apparent with the detailed description of preferred embodiments and the illustration of related drawings as follows.

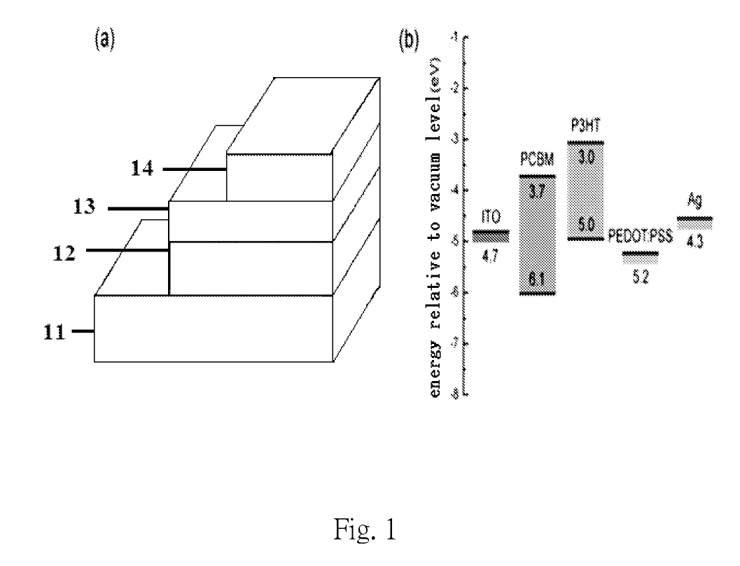

With reference to FIG. 1, (a) shows a structure diagram of one embodiment of the invention and (b) shows an energy band diagram of each layer material of one embodiment of the invention.

In FIG. 1 (a), the bottom layer is a glass substrate with indium tin oxide (ITO) 11, which is coated by a light absorbing layer 12. In this embodiment, the material of the light absorbing layer 12 is the blend heterojunction consisting of C60 derivatives [6,6]-phenyl-C61-butyric acid methyl ester (PCBM) and poly(3-hexylthiophene) (P3HT), a hole transport layer 13 is located above the light absorbing layer 12, the hole transport layer 13 including at least poly 3,4-ethylene dioxy thiophene (poly (3,4-ethylenedioxy-thiophene), PEDOT): polystyrene sulfonic acid (poly (styrene sulfonate), PSS), and isopropyl alcohol (IPA) used as a dilution solvent, wherein the weight ratio of the PEDOT:PSS IPA is 1:5.

And silver used as the material of a metal electrode 14 is deposited in 80 nm thickness on the hole transport layer 13 by thermal evaporation. The area of the device is 4 mm FIG. 1 (b) shows, in this embodiment, the relative position of each energy band of the layers of materials such as ITO, PCBM, P3HT, PEDOT:PSS and Ag, etc.

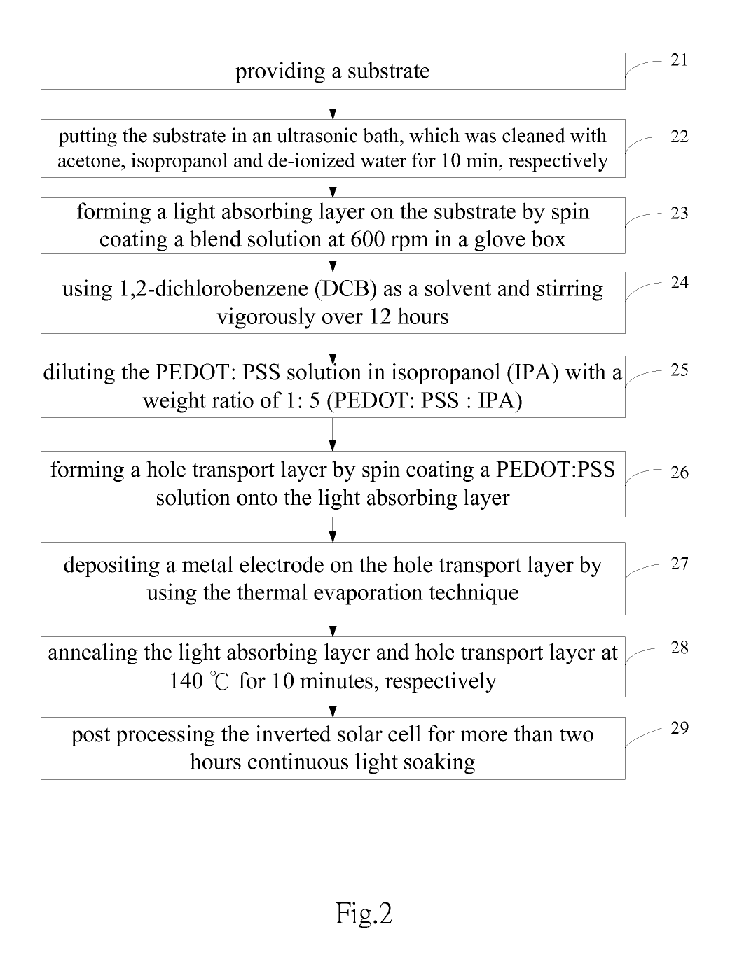

Please refer to FIG. 2, which is a production flow chart showing one embodiment of the invention. First of all, providing a substrate 21, which is a glass substrate coated with indium tin oxide (ITO) film; then putting the substrate in an ultrasonic bath, which was cleaned with acetone, isopropanol and de-ionized water for 10 min, respectively 22; then, forming a light absorbing layer on the substrate by spin coating a blend solution at 600 rpm in a glove box 23.

The light absorbing layer material used in this embodiment is the blend heterojunction consisting of C60 derivatives [6,6]-phenyl-C61-butyric acid methyl ester (PCBM) and poly(3-hexylthiophene) (P3HT), wherein the blend solution of P3HT (17 mg ml⁻¹) and PCBM (17 mg ml⁻¹) was prepared by using 1,2-dichlorobenzene (DCB) as a solvent and stirring vigorously over 12 hours 24; then, diluting the PEDOT:PSS solution in isopropanol (IPA) with a weight ratio of 1:5 (PEDOT:PSS:IPA) 25. After that, forming a hole transport layer by spin coating a PEDOT:PSS solution onto the light absorbing layer 26; depositing a metal electrode on the hole transport layer by using the thermal evaporation technique 27; annealing the light absorbing layer and hole transport layer at 140° C. for 10 minutes, respectively 28; post processing the inverted solar cell for more than two hours with continuous light soaking 29 (the length of continuous light soaking is adjusted according to the selected material, which is not limited to two hours), thus, the inverted solar cell can be provided with irreversible characteristics and maintain highly efficient for a long time.

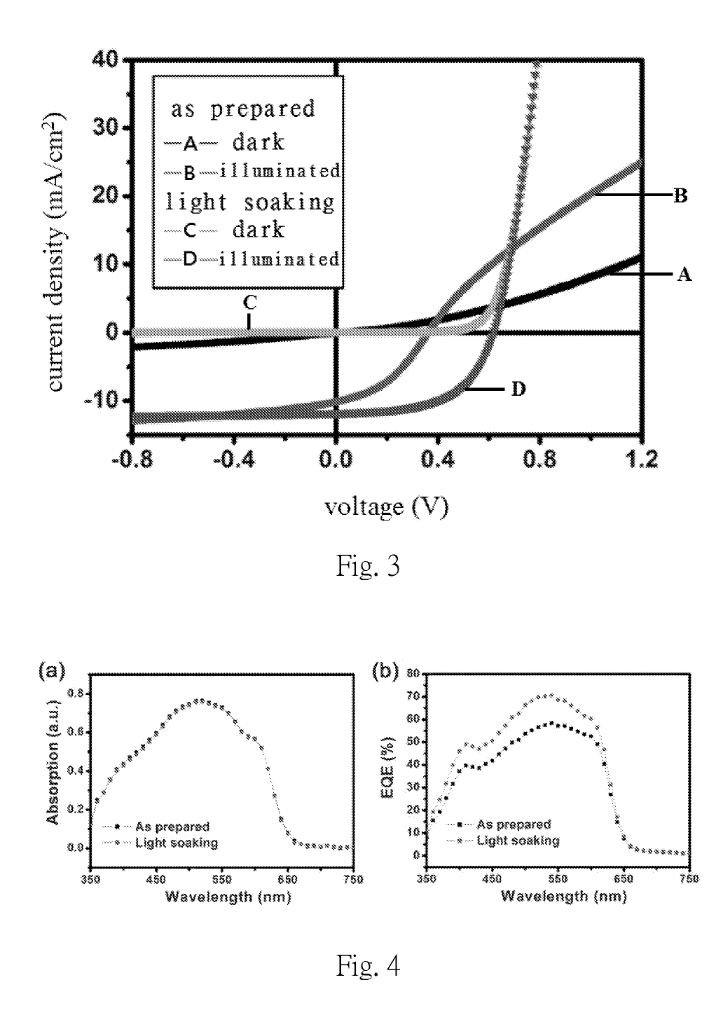

Please refer to FIG. 3, which shows the J-V curve of the devices of the present invention before (as prepared) and after continuous illumination (light soaking) under an AM1.5G solar simulator for 2 hours. Curve A and B represent the dark current and illuminated current of the as-prepared device respectively, C and D represent the dark current and illuminated current of the device after light soaking respectively.

Unlike conventional diode-like behavior, the dark J-V curve A of the as-prepared device exhibits leakage at negative bias and was suppressed at forward bias. The illuminated J-V curve B of the as-prepared device shows similar leakage at negative bias and rises quickly around V=0 V, leading to a small open-circuit voltage (Voc) of 0.36 V.

It is also notable that the current density is also suppressed at forward bias, resulting in an inflection point near Voc. As a result, the as-prepared device yields small fill factor (FF) and poor PCE. For the devices with light soaking, not only the current leakage at the negative bias but the inflection near the Voc disappears in the illuminated J-V curve D, exhibiting normal diode-like characteristics. This disappearance of inflection with light soaking is similar to observation previously reported from inverted organic solar cells with ZnO electron-selective layer.

In this embodiment, the Voc (FF) increases from 0.36 V (0.40) for the as-prepared device to 0.62 V (0.57) for the devices with light soaking.

Because both Voc and FF are significantly enhanced after light soaking, the PCE is also greatly enhanced from 1.46% to 4.10%. The photovoltaic parameters are summarized in Table 1.

TABLE 1

| | J_{sc} mA cm⁻² | V_{oc}/V | FF | PCE (%) |
|---|---|---|---|---|
| As prepared | 10.14 | 0.36 | 0.40 | 1.46 |
| Light soaking | 11.73 | 0.62 | 0.57 | 4.10 |

Please refer to FIG. 4, wherein (a) and (b) show the absorption of the blend layer coated on ITO substrates and the EQE of the inverted devices, with or without light soaking, respectively. It can be seen from FIG. 4(a) that the absorption of blend layer does not change with light soaking. However, in FIG. 4(a), the EQE spectrum of light-soaked device is higher than that of the as-prepared device. This indicates that the light-soaked device has better carrier transport and carrier collection efficiency.

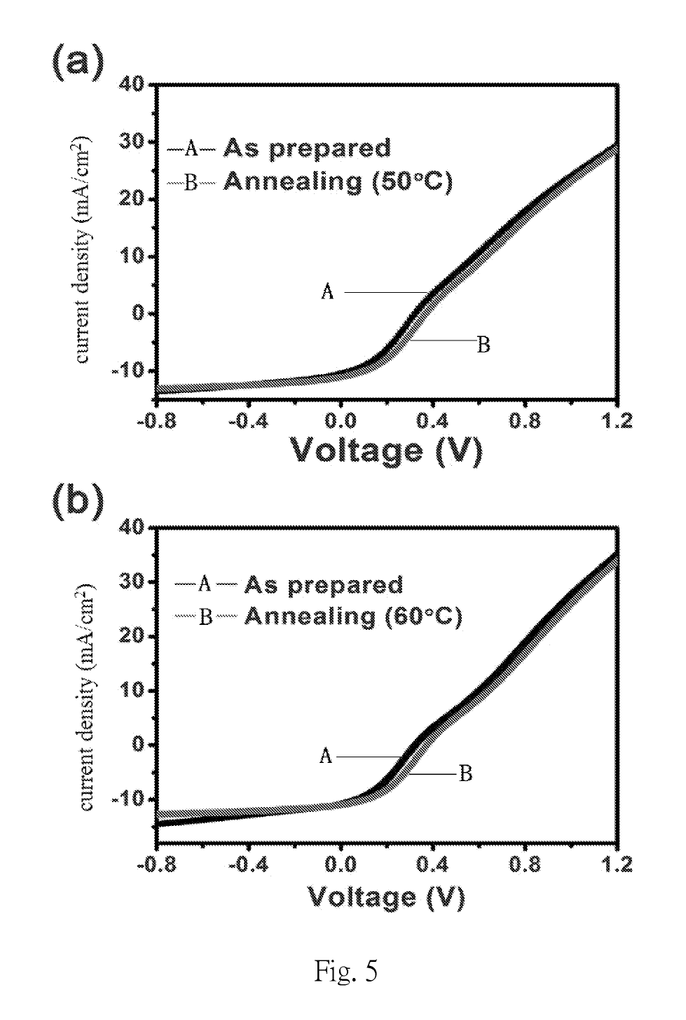

To investigate whether the aforementioned light-soaking induced enhancement is due to the increase in substrate temperature, which is measured to be around 50° C., the effect of post-annealing was studied. Please refer to FIG. 5, wherein (a) and (b) show the illuminated J-V curves of devices which were post-annealed at 50° C. and 60° C., respectively, and the performance parameters are summarized in Table 2.

TABLE 2

| | J_{sc} mA cm⁻² | V_{oc}/v | FF | PCE (%) |
|---|---|---|---|---|
| Device A | | | | |
| As prepared | 10.48 | 0.32 | 0.37 | 1.26 |
| Annealing (50° C. ) | 11.07 | 0.37 | 0.39 | 1.59 |
| Device B | | | | |
| As prepared | 10.85 | 0.32 | 0.37 | 1.30 |
| Annealing (60° C. ) | 10.99 | 0.37 | 0.41 | 1.66 |

Though the leakage current at reverse bias was reduced, the Jsc, Voc, FF and thus PCE of both devices with post-annealing remain nearly unchanged. Hence, the light soaking induced enhancement was not attributed to the increase in substrate temperature during the illumination.

In order to understand the effects of post-treatments, XPS was employed to characterize the surface composition of blend layers. The samples for XPS characterization were prepared in the same way as described previously except that they were not coated with PEDOT:PSS and metal electrode. These samples were then encapsulated with glass and subject to different post treatments.

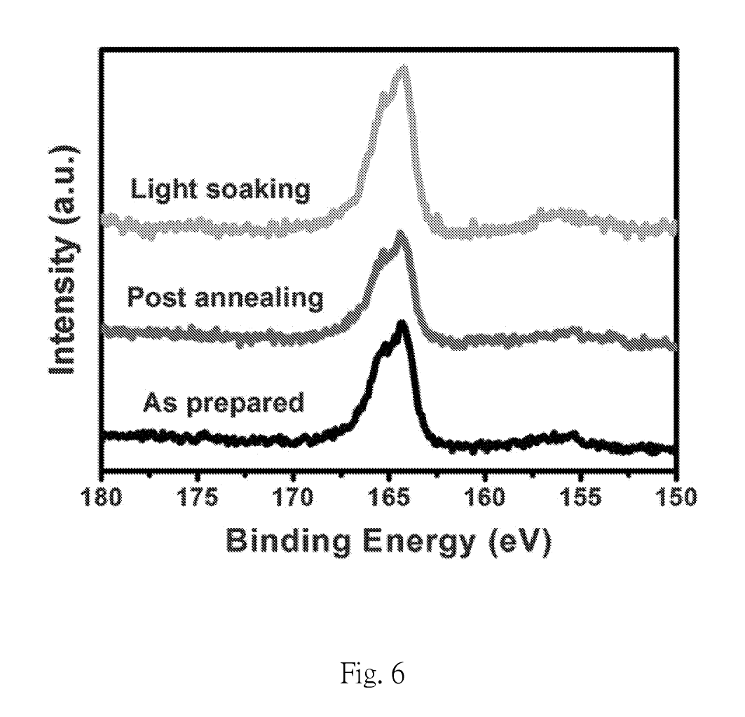

Three types of samples were compared: (A) as prepared, (B) post-annealed at 50° C. for 2 hours and (C) light soaked for 2 hours. The glass covers of the samples were detached immediately before loading into the XPS chamber. Sulfur (S) 2p and carbon (C) 1s signals were detected. Thermo Avantage software (v3.20) was used to calculate the S to C atomic ratios, which in turn were transformed to P3HT to PCBM relative weight percentage. The measured S 2p core levels were shown in FIG. 6 and the calculated results were summarized in Table 3.

It is clear from FIG. 6 that the as-prepared sample and post-annealed sample exhibited similar sulfur S 2p intensities which were obviously lower than that of the sample with light soaking. While the P3HT weight ratio of as-prepared sample and post-annealed sample is around 60%, it was increased to 75% for the light-soaked sample.

Accordingly, P3HT was further segregated at the surface of the blend layer after light soaking. It is noteworthy to mention that XPS provides only the surface concentration within the electron escape depth and techniques such as Time-of-Flight Secondary Ion Mass Spectrometry (TOF-SIMS) depth profiling, XPS depth profiling and ellipsometry should be used to provide more detailed information on vertical concentration profile, which are essential to understand the microscopic mechanism and to devise post-processing with reduced time.

TABLE 3

| | |
|---|---|
| Atom (%) | Weight (%) |

| | C 1s | S 2p | PCBM | P3HT |
|---|---|---|---|---|
| As prepared | 94.93 | 5.07 | 40.1 | 59.9 |
| Post-annealing | 94.77 | 5.23 | 38.3 | 61.7 |
| Light soaking | 93.44 | 6.56 | 24.5 | 75.5 |

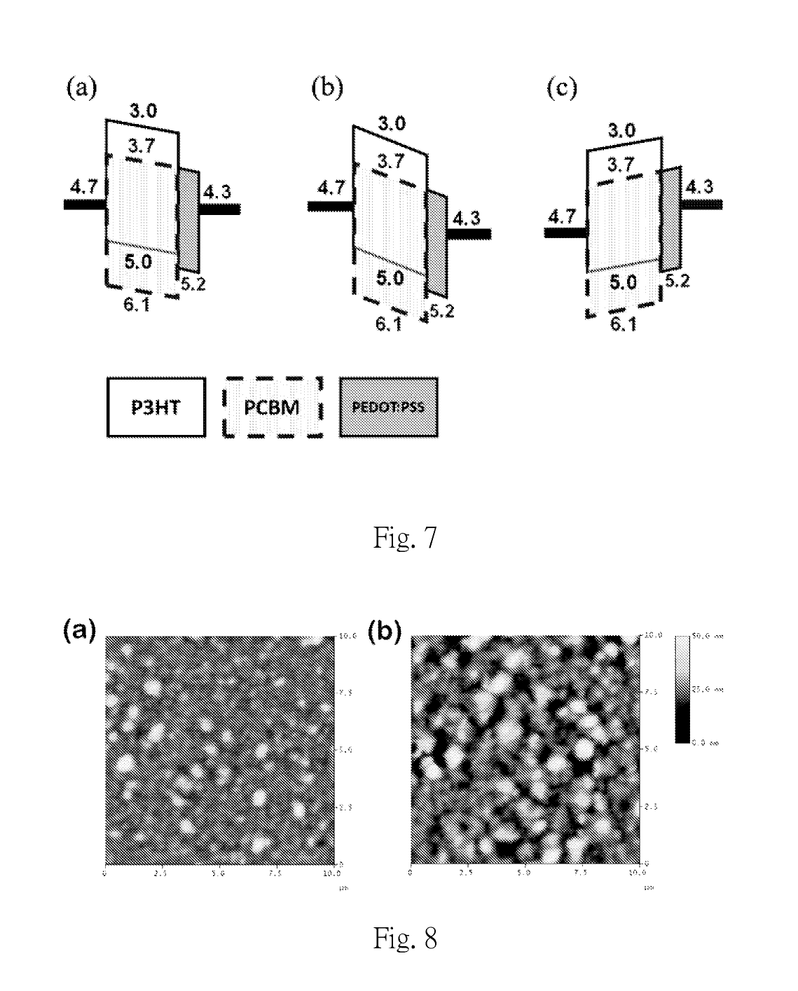

Please refer to FIG. 7, which is the band diagrams of one embodiment of the invention, wherein (a) is V=0 V, (b) is forward bias and (c) is reverse bias, which help to understand the effects of light soaking on the J-V curves.

As shown in FIG. 7(a), since ITO has a larger work function than silver, the built-in potential disfavors electron (hole) transport to ITO (Ag) electrode at V=0V. Besides, it was reported that PEDOT:PSS is not an effective electron blocking layer. Photo-carriers might travel toward wrong electrode and recombine among themselves due to their more uniform distribution within the devices. Consequently, the early rise of current density around V=0V for the as-prepared sample, as observed from curve B in FIG. 3, was expected.

With light soaking for 2 hours, there is much more P3HT segregating at the interface between the blend layer and PEDOT:PSS. The segregated P3HT layer would efficiently block the electrons transport from PCBM to the Ag anode, leading to blocked electrons accumulated at the interface. The accumulation of electrons at the blend/PEDOT:PSS interface decreases the bulk electric field and enhances the electron diffusion to the ITO cathode. The rise of the current density observed at V=0V from the as prepared sample is therefore slower, leading to increased Voc.

It is worth noting that since the energy barrier against electron injection from electrodes into the device is much larger than that against hole injection, the electron injection in our devices is negligible at all biases. It is also worth noting from FIG. 7(b) that the forward current results mainly from the collection of photo-carriers as well as the injection of holes from the Ag anode. The inflection of J-V curves around Voc for the as-prepared device indicates that the hole injection from the anode is limited and the current comprises mostly the photo carriers, leading to suppressed current at forward bias (as shown in FIG. 3).

On the other hand, the suppression of hole injection in the light soaked device is lifted and the forward current exhibits normal diode-like characteristics. In view of the P3HT surface segregation being induced by light soaking, we tentatively attributed the suppression of hole injection to the limited P3HT surface concentration. It is remarkable that a mere increase in the P3HT surface composition ratio from 59% to 75% eliminates the current suppression and restores the diode-like J-V characteristics.

From the band diagram shown in FIG. 7(c), the leakage at reverse bias for the as-prepared devices should result mainly from the hole injection from ITO into the active layer. The observation of diminished leakage current at reverse bias in the case of the light-soaked device also suggests that the relative amount of PCBM at the ITO/blend interface increases after light soaking, thus inhibiting the hole injection ITO from entering the blend layer.

Please refer to FIG. 8, wherein (a) and (b) shows the AFM images of the P3HT/PCBM blend surface of the as-prepared and light-soaked sample respectively, in one embodiment of the invention.

Larger aggregation is observed on the blend surface of the light-soaked sample than the as-prepared sample. The surface roughness increases from 3.9 nm to 6.9 nm with light soaking. The results indicate that rough surface morphology may reduce the charge-transport distance and increase the Jsc. The increase in Jsc from 10.1 to 11.7 mA cm-2 is therefore attributed to the rougher surface morphology induced by light soaking.

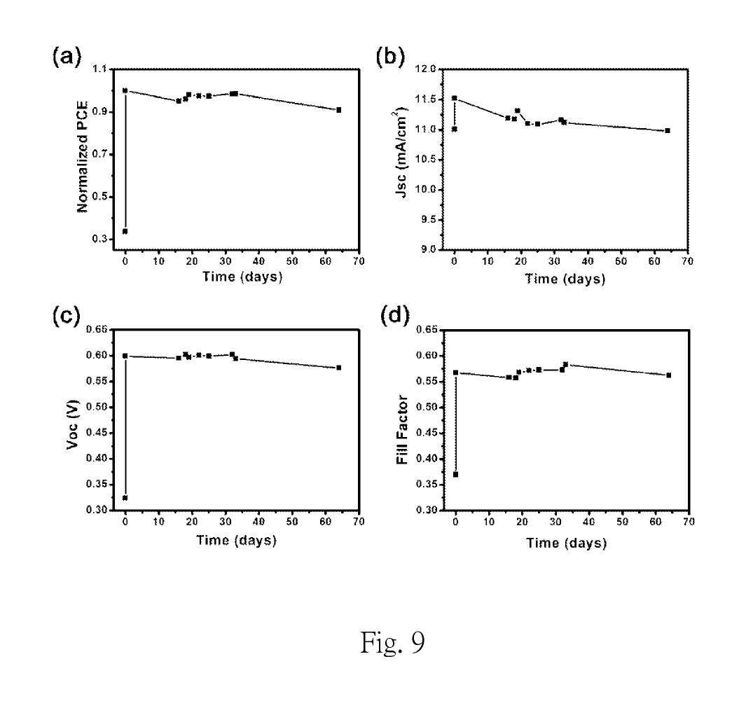

Please refer to FIG. 9, which shows the evolution of the performance parameters as a function of storage time, wherein (a) is normalized power conversion efficiency (b) is the short-circuit current density (c) is the open circuit voltage (d) is the fill factor, wherein day 0 denotes the day on which the device was prepared and light soaked. Although Jsc in FIG. 1 (b) slightly decreased, Voc in FIG. 1 (c) and FF in FIG. 1 (d) remained relatively constant and the PCE in FIG. 1 (a) of the device maintains more than 90% over the entire time duration.

It was also observed that the PCE, Voc and FF increased slightly when the device was moved to be in contact with an air environment. The slight improvement may result from the oxidation of silver electrode, which was reported to increase the Ag work function. With larger Ag work function, the built-in potential would favor the charge being transported to the electrode in the inverted OPV device. It is clear from this result that the light-soaked device shows good air stability and the light-induced enhancement is irreversible, as compared to reversible enhancement reported in the conventional techniques.

Many changes and modifications in the above described embodiment of the invention can, of course, be carried out without departing from the scope thereof. Accordingly, to promote the progress in science and the useful arts, the invention is disclosed and is intended to be limited only by the scope of the appended claims.

What is claimed is:

1. An inverted organic solar cell, comprising:
a substrate;
a light absorbing layer located on the substrate;
a hole transport layer located on the light absorbing layer; and
a metal electrode located on the hole transport layer,
wherein, the inverted organic solar cell can achieve high conversion efficiency rates for a long time after the inverted organic solar cell has passed through a continuous illumination for a period of time.

2. The inverted organic solar cell of claim 1, wherein the substrate is a glass or plastic substrate coated with transparent conductive film such as indium tin oxide (ITO) or aluminum doped zinc oxide (ZnO:Al).

3. The inverted organic solar cell of claim 1, wherein a material of the light absorbing layer is one selected from the following group consisting of: P3HT(3-hexylthiophene), C60 derivative, PTB1, PTB2, PTB3, PTB4, PTB5, PTB6, PTB7 and the group consisting of any combinations thereof.

4. The inverted organic solar cell of claim 1, wherein the metal electrode comprises silver.

5. The inverted organic solar cell of claim 1, wherein a length of the period of time is adjusted depending on the selected material thereof.

6. A production method of inverted organic solar cell, comprising the following steps:
(a) providing a substrate;
(b) forming a light absorbing layer on the substrate;
(c) forming a hole transport layer on the light absorbing layer; and
(d) depositing a metal electrode on the hole transport layer,
wherein, the inverted organic solar cell can achieve high conversion efficiency rates for a long time after the inverted organic solar cell has passed through a continuous illumination for a period of time.

7. The production method of claim 6, wherein step (a) the substrate is a glass or plastic substrate coated with transparent conductive film such as indium tin oxide (ITO) or aluminum doped zinc oxide (ZnO:Al).

8. The production method of claim 6, wherein a material of the light absorbing layer is one selected from the following group consisting of: P3HT(3-hexylthiophene)-C60 derivative PTB1 [symbol] PTB2 [symbol] PTB3 [symbol] PTB4 [symbol] PTB5 [symbol] PTB6 [symbol] PTB7 and the group consisting of any combinations thereof.

9. The production method of claim 6, wherein the metal electrode is one selected from the following group consisting of: silver, gold and metal groups.

10. The production method of claim 6, wherein a length of the period of time is adjusted depending on the selected material thereof.
